(19) United States
(12) Patent Application Publication
(10) Pub. No.: US 2012/0152316 A1
(43) Pub. Date: Jun. 21, 2012

(54) TRACKING DEVICE FOR A PHOTOVOLTAIC SYSTEM, AND METHOD FOR INSTALLING SUCH A TRACKING DEVICE

(75) Inventors: HANS-PETER FISCHER, WENDELSTEIN (DE); RUDOLF GÜMPELEIN, HERRIEDEN (DE)

(73) Assignee: TECNOSUN SOLAR SYSTEMS AG, NEUMARKT I.D. OPF. (DE)

(21) Appl. No.: 13/354,860

(22) Filed: Jan. 20, 2012

Related U.S. Application Data
(63) Continuation of application No. PCT/EP2010/003164, filed on May 25, 2010.

(30) Foreign Application Priority Data
Jul. 20, 2009 (DE) 10 2009 034 144.7

(51) Int. Cl. H01L 31/052; H01L 31/18

(52) U.S. Cl. 136/246; 29/890.033

(57) ABSTRACT

A tracking device contains, for in each case one photovoltaic module, a supporting framework, which has a vertical tracking device and a horizontal tracking device which is forcibly mechanically coupled to the latter. The vertical tracking device contains a supporting structure, which is a supporting mast and is mounted in a rotatable manner about a vertical axis. In operation, vertical tracking is executed with the aid of an electromotive drive, the actuating movement of which is transmitted to the supporting structure. The horizontal tracking device contains in particular an elevation element, which defines a mechanical guide track having different height levels. In operation, the height levels defined by the guide track are transmitted to the photovoltaic module via a mechanical coupling device, in the event of a rotational movement of the supporting structure about the vertical axis, in order to create a pivoting movement about the horizontal axis.

### CROSS-REFERENCE TO RELATED APPLICATION

This is a continuation application, under 35 U.S.C. §120, of copending international application No. PCT/EP2010/003164, filed May 25, 2010, which designated the United States; this application also claims the priority, under 35 U.S.C. §119, of German patent application No. DE 10 2009 034 144.7, filed Jul. 20, 2009; the prior applications are herewith incorporated by reference in their entirety.

### BACKGROUND OF THE INVENTION

### Field of the Invention

The invention relates to a tracking device for a photovoltaic system.

A tracking device of this kind can be gathered from European patent EP 1 710 651 B1.

In photovoltaic systems, the achievable energy yield depends on the incidence angle of the sun in relation to the photovoltaic module, and so, in order to increase the energy yield, it is expedient to use devices which make the photovoltaic modules of the system track the position of the sun, which changes depending on the time of year or day. In this case, mention should first of all be made of vertical tracking, in which the photovoltaic module is made to track the sun's path by rotation of the supporting structure that carries the module about an axis which is substantially vertical with respect to the surface of the earth. In addition, in the case of biaxial tracking, horizontal tracking is possible in that the photovoltaic module is pivoted or inclined in a horizontal axis, so that ideally a right angle with respect to the sun is ensured.

However, with such tracking devices, a separate drive is required both for tracking about the vertical axis and for tracking about the horizontal axis, in order to produce the necessary actuating movements. As a result, in electrical driving modes, a plurality of transmissions, motors and control units are required, with a possibly costly control device also being required in each case. Associated with this are considerable costs for photovoltaic systems which have such biaxial tracking. As a result, photovoltaic systems for tracking have hitherto been able to achieve only small market shares, since the additional energy yield of about 35% is largely canceled out by the additional costs to be incurred.

In order to solve this problem, according to European patent EP 1 710 651 B1 a forced mechanical coupling is provided between the vertical and the horizontal tracking. In this case, there is provided an elevation element which is denoted as curved ring or curved disk and defines a curved track having different height levels. Via a coupling device, which is in the form of an articulated arm linkage, the different height levels are transmitted to the photovoltaic module during vertical tracking, i.e. a rotational movement about the vertical axis, in such a way that pivoting about the horizontal axis takes place. In this case, the coupling device contains a coupling element which travels in operation along the curved or guide track of the elevation element.

### SUMMARY OF THE INVENTION

It is accordingly an object of the invention to provide a tracking device for a photovoltaic system, and a method for installing such a tracking device which overcome the above-mentioned disadvantages of the prior art methods and devices of this general type.

The object is achieved according to the invention by a tracking device being overall in the form of a biaxial tracking device for both vertical and horizontal tracking. Horizontal tracking takes place in this case via forced mechanical coupling to the vertical tracking, without an additional drive or an additional actuation device for the horizontal tracking being necessary and in particular also provided.

The tracking device contains, for in each case one photovoltaic module, a supporting framework, which has a vertical tracking device and a horizontal tracking device which is forcibly mechanically coupled to the latter. In this case, the vertical tracking device contains a supporting structure, which is preferably in the form of a supporting mast and is mounted in a rotatable manner about a substantially vertical axis. In operation, vertical tracking is executed with the aid of an in particular electromotive drive, the actuating movement of which is transmitted to the supporting structure. The horizontal tracking device contains in particular an elevation element, which defines a mechanical guide track having different height levels. In operation, the height levels defined by the guide track are transmitted to the photovoltaic module with the aid of a mechanical coupling device, in the event of a rotational movement of the supporting structure about the vertical axis, in order to create a pivoting movement about the horizontal axis. In this case, the coupling device contains a coupling element, which is configured preferably as a fork element and in operation travels along the mechanical guide track. The mechanical coupling device is preferably connected in a rotationally fixed manner to the supporting structure, so that in the event of a rotational movement about the vertical axis, the mechanical coupling device travels along the guide track. The elevation element is preferably connected in a rotationally fixed manner to an anchoring element, via which the supporting framework is fastened at the bottom to the provided installation surface for the photovoltaic system. The anchoring element is for example a ground anchor, with a separate ground anchor being assigned to each supporting framework. Alternatively, the anchoring element can also be a supporting profile structure, which is provided for example in the case of (flat) roof installations.

A mechanical guide track having different height levels is generally understood to mean that, by way of the guide track, different vertical distances from the photovoltaic module are predefined, the vertical distances then leading to a different inclination of the photovoltaic module about the horizontal axis. In a preferred embodiment, the guide track is formed such that in plan view it extends in a circle around the supporting mast and has elevations and depressions in order to define the different height levels. In an angled state of the guide track the latter thus extends in an undulating, for example sinusoidal, form. In particular, the guide track is formed by the abovementioned curved ring. A curved ring is in this case understood to mean a rod which is formed into a ring and extends along a predefined curve.

On account of the special configuration of the elevation element, depending on the rotational or azimuth angle, a different height level of the guide track is therefore generally transmitted to the photovoltaic module and thus, depending on the azimuth angle, a defined horizontal inclination angle of the photovoltaic module is forcibly set.

It is particularly advantageous in the case of the tracking device that the supporting framework has at least one adjusting device, via which the rotational orientation of the elevation element with regard to the anchoring element and/or the rotational orientation of different part regions of the supporting mast with respect to one another can be adjusted. These adjusting devices serve to simplify assembly or else for easy readjustment during operation. The configuration of these adjusting devices is based on the finding that, on account of the forced mechanical coupling between the vertical and horizontal tracking devices, precise alignment of the supporting framework in a setpoint orientation is necessary. In particular in the case of a photovoltaic system having a multiplicity of supporting frameworks which are connected together and the vertical tracking of which takes place via a common drive motor, as is provided for example in the case of the tracking device according to European patent EP 1 710 651 B1, there is the problem that, on account of tolerances and play in the drive train, the individual photovoltaic modules assume different azimuth angles, i.e. different rotational angles about the vertical axis.

The division of the supporting structure into two part regions, which can be rotationally adjusted with respect to one another, leads to the advantage that, after the system has been put into operation, when, on account of such play and tolerance effects, the vertical orientation between different supporting frameworks is not entirely synchronous, the vertical rotational position of individual supporting frameworks can be set easily without the supporting framework as a whole having to be rotated with regard to the anchoring element.

The same applies to the adjusting device for rotationally positioning the elevation element. The guide track which is defined by the latter and has the different height levels has to be aligned precisely with regard to the points of the compass so that the highest point of the guide track points precisely toward the south. In the case of the tracking device known from European patent EP 1 710 651 B1, the elevation element is connected in each case firmly to the anchoring element, for example by welding, etc., thus resulting in highly precise orientation of the anchoring element. This is sometimes difficult, in particular in the case of a photovoltaic system having a multiplicity of individual supporting frameworks. On account of the adjusting device, it is thus easily possible subsequently to precisely position the elevation element in the setpoint position.

The adjusting device for rotationally adjusting the elevation element is preferably independent of the adjusting device for rotationally adjusting the two part regions of the supporting structure with respect to one another. Preferably, they are used in combination, resulting in a double adjusting option.

According to a preferred embodiment, the elevation element is to this end connected to a fastening foot, in particular in a rotationally fixed manner, for example by welding, etc., wherein the fastening foot can be fastened reversibly in different rotational positions with regard to the anchoring element. With regard to a simple configuration of the adjusting option, the fastening foot and/or the anchoring element has at least one slot guide, which is curved in particular along a circular path, for a fastening element such as a screw, for example. Furthermore, the fastening foot expediently has a fastening plate, which is for example circular, for resting in a planar manner on the anchoring element. This serves for easy assembly and high mechanical stability.

With regard to the second adjusting device for the rotational adjustment of the part regions of the supporting structure with respect to one another, it is provided that the part regions can be fixed reversibly together at their dividing point in different rotational positions with respect to one another. In particular, the two part regions of the supporting mast are connected together via flanges at the dividing point. Here, too, at least one of the flanges has a slot guide, which is preferably curved along a circular path, for a fastening element such as a screw. The flanges ensure easy assemblability and high mechanical stability. It is usually provided that the drive for vertical tracking acts on one of the two part regions, in particular the lower part region.

According to an expedient development, it is provided that a spring element is arranged between the coupling element, which is for example in the form of a fork element, and the supporting mast.

On account of the spring element, which may preferably be in the form of a compression spring, the pressing force between the fork element and the elevation element, which is formed for example as a curved ring, is reduced. The spring element thus counteracts the considerable inertial forces of the photovoltaic modules, which, in the absence of a spring element, would otherwise produce high frictional forces. In particular, the energy requirement for biaxial tracking can be considerably reduced further by the spring element provided according to the invention, and so a larger number of tracking devices can be driven with a single drive.

The spring element is preferably arranged such that it exerts a torque on the coupling element, the torque counteracting the torque produced by the photovoltaic module. In this way, the torque, which can be considerable under certain circumstances and is produced by the photovoltaic module, is at least partially compensated by the spring element, and so the forces acting on the curved ring can likewise be reduced. The low friction between the curved ring and the fork element leads to a lower requirement for drive energy.

In a preferred development, it is provided that the coupling element has at least one rotatably mounted sleeve, by way of which the coupling element is supported on the guide track of the elevation element. During the tracking of the photovoltaic module, the rotatably mounted sleeves roll on the curved ring, and so the tracking demands only a small energy requirement.

Expediently, the coupling element is in this case configured as a fork element having two fingers which grip the elevation element in the form of a curved ring between one another. The curved ring is thus guided between the rotatably mounted sleeves.

In a preferred development, a protective collar is attached to the supporting mast in the region of the spring element. On account of the to some extent considerable forces and the variation therein, there is the risk that the supporting mast will be damaged by the supporting of the spring element, so that for example a protective coating is worn away. This is prevented by way of the protective collar, which consists for example of a suitable abrasion-resistant plastic or else of a suitable metal.

The entire supporting framework consists preferably of metal, which has to be weather-resistant on account of the necessary outdoor installation. Usually, galvanized metal structures are used. The rotational movement of the individual parts with respect to one another may result in undesired wear phenomena but also running difficulties. The latter are in particular also caused by the surface roughnesses produced during the galvanizing process. In order to reduce these problems, in a preferred embodiment it is provided that a sliding element, in particular a sliding sleeve, is arranged between the supporting mast and the fastening foot, on which the supporting mast is rotatably arranged. The sliding element is in this case arranged preferably in a loose manner and consists of a preferably abrasion-resistant plastic or else of a suitable metal. Usually, the fastening foot has a vertically oriented upright or guiding tube, which guides the supporting mast. To this end, the latter is selectively fitted over the upright tube or is plugged into the upright tube. In the configuration as a sliding sleeve, a radial guide between the supporting mast and the guiding tube is at the same time defined via the sliding sleeve. The sliding sleeve can in this case extend along the entire length of the guiding tube. However, it is preferably provided that a plurality of sliding sleeves, in particular two sliding sleeves, are provided, specifically in particular at the two end sides of the guiding tube.

In order to keep the surface pressure force between the supporting mast and the fastening foot low, the supporting mast has a bottom flange, by way of which it is supported on at least a part of the sliding element. If the sliding element is in the form of a sleeve, this sleeve preferably likewise has a flange.

In a preferred development, there is provided a storm protection device, which secures the supporting mast against being detached from the anchoring element and in particular from the fastening foot. To this end, provision is preferably made of a retaining element, which forms a form fit, which acts in the axial direction, between the fastening foot and the supporting mast, but at the same time still enables the rotational movement. In particular, there is provided a retaining lug, which is fastened to the fastening foot and overlaps the bottom flange of the supporting mast in a form-fitting manner, preferably without coming into contact therewith.

In order to transmit the actuating movement of the common motor, which is provided preferably for a plurality of supporting frameworks, there is preferably arranged—as in the tracking device known from European patent EP 1 710 651 B1—a hollow-cylindrical or tubular driver element which is arranged concentrically with the supporting mast and is connected in a rotationally fixed manner thereto, for example by struts. Provided in order to transmit the actuating movement of the motor is an elastic drive device, what is known as a wraparound device, which wraps around the driver element. Such a drive device is for example a cable, a belt, a strap, a chain or the like. The drive device, preferably a cable, is usually wrapped a number of times around the driver element. In order now to ensure a connection that is as slip-free as possible between the drive device and the driver element, a friction brake is generally formed in particular by structuring the lateral surface of the driver element. To this end, a guide slot, in which the drive device is accommodated in the assembled state, is preferably introduced in the driver element. In operation, the cable is therefore in the tensioned state at the edges of the guide slot, which are opposed in the circumferential direction, as a result of which the friction is increased and slip is prevented.

According to a preferred development, the flange of the lower part region of the supporting mast forms an upper termination for the driver element, i.e. the dividing point is arranged at the upper end of the driver element. In the hollow-cylindrical configuration of the driver element, this flange forms preferably a cover, so that a closed-off structural unit is formed. The bearing region of the supporting mast on the foot plate is better protected as a result.

Preferably, the tracking device contains a multiplicity of supporting frameworks, to which a common drive is assigned, wherein the actuating movements exercised by the drive are transmitted to the supporting mast via a drive device, such as the cable, for example. In this case, the supporting frameworks are usually oriented in a row alongside one another. For example, 10 to 30 supporting frameworks are assigned to a common drive. A photovoltaic system can consist of a number of such rows.

Accordingly, it is provided that, in order to install the tracking device, with the aid of the adjusting devices the elevation element and/or the upper part region of the supporting structure are moved into a defined setpoint position. In particular in the latter case, an actuating movement is transmitted at least once beforehand from the drive to the supporting structure in order to take account of tolerance and play degrees of freedom upon initial operation, such as tensioning the cable, etc., for example. Specifically, in the arrangement of a multiplicity of supporting frameworks, upon initial operation the previously assumed rotational position is usually adjusted so that the individual photovoltaic modules are oriented in different vertical rotational positions.

Other features which are considered as characteristic for the invention are set forth in the appended claims.

Although the invention is illustrated and described herein as embodied in a tracking device for a photovoltaic system, and a method for installing such a tracking device, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE SEVERAL VIEWS OF THE DRAWINGS

FIG. 1 is a simplified illustration of a tracking device having a plurality of photovoltaic modules mounted on in each case one supporting framework, according to the prior art;

FIG. 2 is a diagrammatic, perspective view of a supporting framework according to the invention;

FIG. 3 is a diagrammatic, sectional view of a detail of the supporting framework in the region of a fastening foot;

FIG. 4 is a diagrammatic, perspective view obliquely from below of a part region illustrated in FIG. 3;

FIG. 5 is a side view of a coupling element configured as a fork element having guiding sleeves pushed onto fork ends and having a compression spring pushed onto an extending arm;

FIG. 6 is a diagrammatic, perspective view of the fork element according to FIG. 4 without guiding sleeves and spring element;

FIG. 7 is a diagrammatic, perspective view of a detail of a tracking device having a supporting framework without adjusting devices, having a photovoltaic module fitted on the supporting framework; and

FIG. 8 is a diagrammatic, perspective view the tracking device according to FIG. 7 from a different perspective.

### DETAILED DESCRIPTION OF THE INVENTION

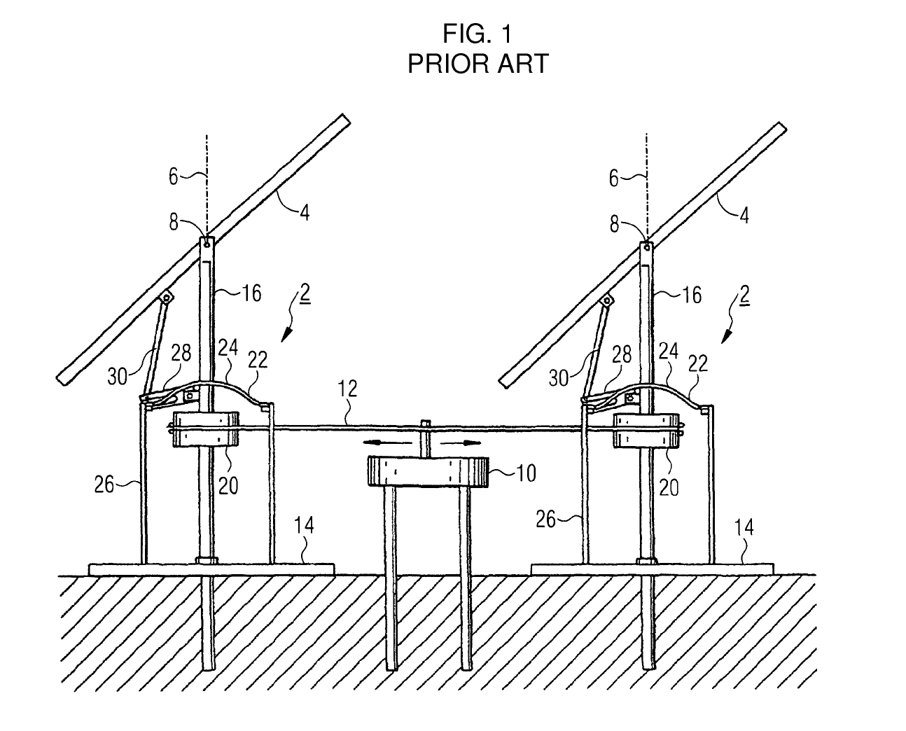

In the figures, identically acting parts are provided with the same reference signs. Referring now to the figures of the drawing in detail and first, particularly, to FIG. 1 thereof, there is shown a photovoltaic system, known from the prior art according to European patent EP 1 710 651 B1, having a biaxial tracking device. The photovoltaic system has a multiplicity of supporting frameworks 2, which each support a photovoltaic module 4. In the exemplary embodiment, two supporting frameworks 2 are illustrated by way of example. Each of the photovoltaic modules 4 is pivotable about a vertical axis 6 and about a horizontal pivot axis 8. Provided for joint adjustment and tracking is a common drive motor 10 which transmits an actuating movement to the respective supporting framework 2 via a drive device, which in the exemplary embodiment is in a form of a cable 12, in order to exercise a synchronous rotation of the individual supporting frameworks 2 about their respective axis 6 for vertical tracking. In the event of such vertical tracking, horizontal tracking about a pivot axis 8 is forcibly exercised at the same time via a forced mechanical coupling.

The supporting framework 2 is generally fastened to the ground via an anchoring element 14. In the exemplary embodiment, a separate anchoring element 14 is assigned to each supporting framework 2. The anchoring element 14 contains a ground plate having an anchoring post that is driven into the ground.

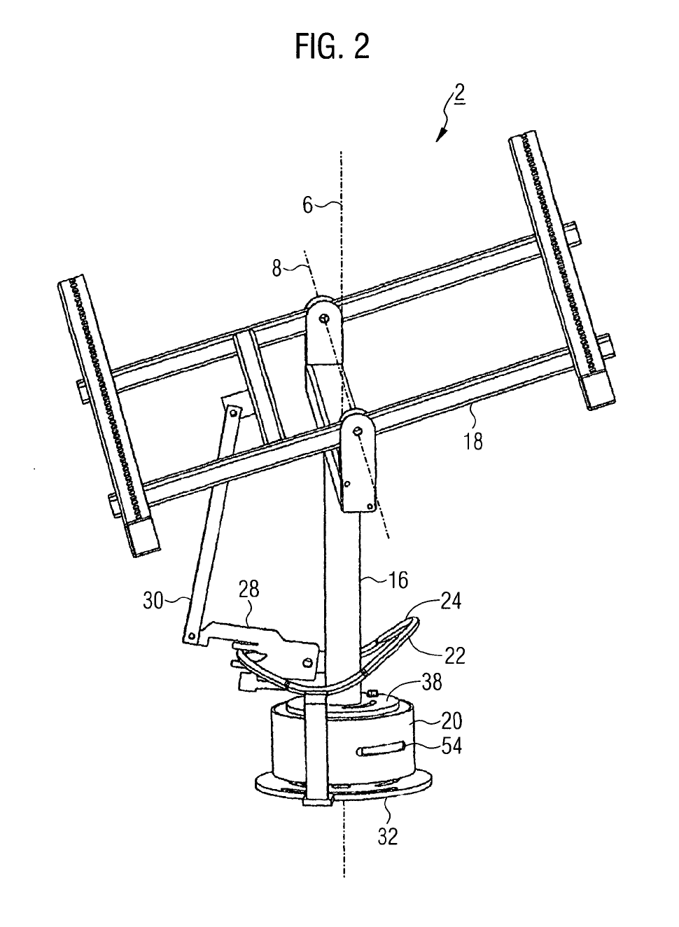

A supporting mast 16 is arranged in a rotatable manner on the anchoring element 14. The supporting mast 16 extends in the vertical direction and is oriented concentrically with the vertical rotational axis 6. At its upper end, the supporting mast 16 is connected to a supporting frame 18 (see in particular FIG. 2). The horizontal pivot axis 8 crosses the supporting mast 16 or an extension thereof. In order to transmit the actuating movement of the drive motor 10, a driver element 20, which is formed as a hollow cylinder and is connected to the supporting mast 16 for example via connecting struts, is fastened on the supporting mast 16. The cable 12 is guided around the driver element 20 and wraps around the latter preferably a number of times. In the exemplary embodiment illustrated, the supporting mast 16 together with the driver element 20 form elements of a supporting structure of the supporting framework 2 for vertical tracking, the supporting structure being mounted in a rotatable manner about the vertical axis 6, and thus form at the same time also the essential elements of a vertical tracking device.

For forcibly coupled vertical tracking, a horizontal tracking device is provided. The latter contains an elevation element, which is in the form of a curved ring 22 in the exemplary embodiment and is an annular element which is formed concentrically around the supporting mast 16 and defines a mechanical guide track 24 having different height levels. The curved ring 22 is connected firmly to the anchoring element 14 via fastening elements 26. Furthermore, the horizontal tracking device contains a mechanical coupling device, which consists in the exemplary embodiment of an articulated arm linkage. The latter contains substantially a coupling element 28, which is fastened pivotably thereto by way of its supporting-mast end. At its opposite end, it is connected likewise pivotably to a lever arm 30 which is in turn connected in a rotatable manner to the supporting frame 18 (see FIG. 2). The coupling point of the lever arm 30 on the supporting frame 18 is spaced apart from the horizontal pivot axis 8, and so a vertical actuating movement of the lever arm 30 results in horizontal pivoting.

The coupling element 28 is forcibly guided by the guide track 24 in the event of a rotational movement about the vertical axis 6 and therefore travels along the curved track having the different height levels that is predefined by the elevation element (curved ring 22). In the exemplary embodiment, the coupling element 28 is in the form of a fork element, the two fork ends of which engage around the curved ring 22.

During operation of the photovoltaic system, it is important for the individual photovoltaic modules 4 to be precisely aligned for as great efficiency as possible. It has been shown that upon starting up or during ongoing operation, the problem can occur that, for example on account of play and tolerance effects in the drive train, the individual supporting frameworks 2 and thus photovoltaic modules 4 assume different rotational positions with regard to their rotational position about the vertical axis 6. Furthermore, it has been shown that it is difficult to position the elevation element 22 precisely in the desired setpoint rotational position. The highest point of the elevation element 22 has to be oriented toward the south.

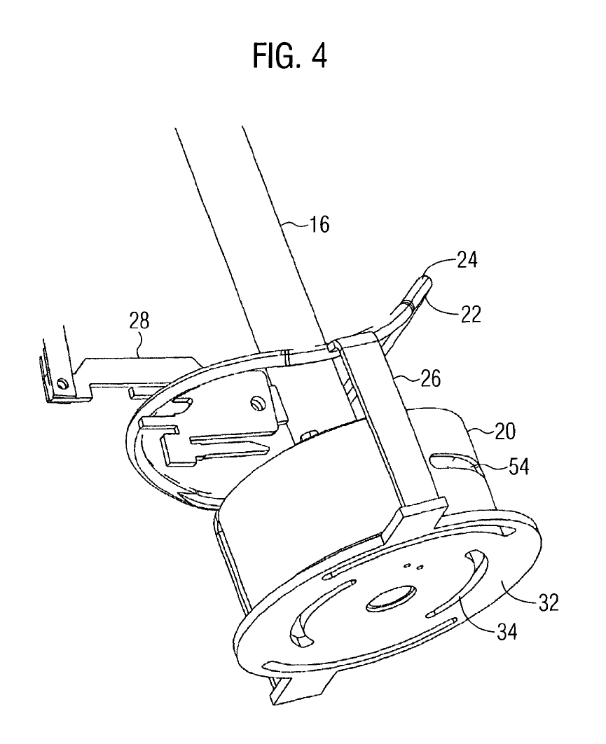

In order to solve these problems, a double adjusting device is provided, as is explained in more detail in the following text in conjunction with FIGS. 2 to 4. The first adjusting device serves to adjust the elevation element 22 in the desired setpoint rotational position with regard to the vertical axis 6. This first adjusting device contains substantially a fastening foot 32, which in the exemplary embodiment is in the form of a circular fastening plate and by way of which the entire supporting framework 2 is fastened to the anchoring element 14. The fastening foot 32 is in this case connected to the anchoring element 14 by releasable fastening, in particular screw fastening, such that, after the fastening has been released, the rotational position of the fastening foot 32 is variable. To this end, in the exemplary embodiment, the fastening foot 32 has two slot guides which extend in the form of a circular arc and through which the fastening screws can be plugged. On account of this configuration, it is therefore possible, after installation of the supporting frameworks 2 on the anchoring elements 14, still to change and precisely set the rotational position in particular of the elevation element 22 with respect to the respective anchoring element 14. Precise alignment of the anchoring elements 14 is therefore not necessary.

The second adjusting device serves to adjust the rotational position of the respective photovoltaic module 4 about the vertical axis 6 in the event of not precise synchronous alignment with the other photovoltaic modules 4. To this end, the supporting mast 16 is subdivided into an upper part region 36A and a lower part region 36B. These two part regions 36A, 36B are fastened together in a reversible and releasable manner at a dividing point, specifically such that their relative rotational position with respect to one another can be set. In this case, the dividing point is arranged generally below a coupling point at which the coupling device is fastened to the supporting mast. Furthermore, the dividing point is arranged above a coupling point at which the drive force exerted by the drive train is transmitted to the supporting mast 16.

To this end, in each case a fastening flange 38 is formed at the ends of the two part regions 36A, 36B. At least one of the fastening flanges 38 is formed with slot guides 34 in a similar manner to the fastening foot 32. The rotational position of the upper region of the supporting framework 2 can therefore be readjusted easily without this having an effect on the lower part region 36B, to which the drive force of the drive 10 is transmitted. Thus, via the dividing point, an uncoupling option is generally defined between the drive train and the upper part region.

In the exemplary embodiment, the flange 38 of the lower part region 36B forms at the same time an upper cover for the hollow-cylindrical driver element 20. Overall, as a result, a largely closed-off internal cavity is created, in which in particular the bearing point of the supporting mast 16 is accommodated in a protected manner. The fastening flange 38 is in particular somewhat spaced apart from the driver element 20, and so as little friction as possible occurs during vertical tracking. In contrast to the exemplary embodiment illustrated, the fastening flange 38 is arranged preferably above the driver element 20 and covering its edge sides.

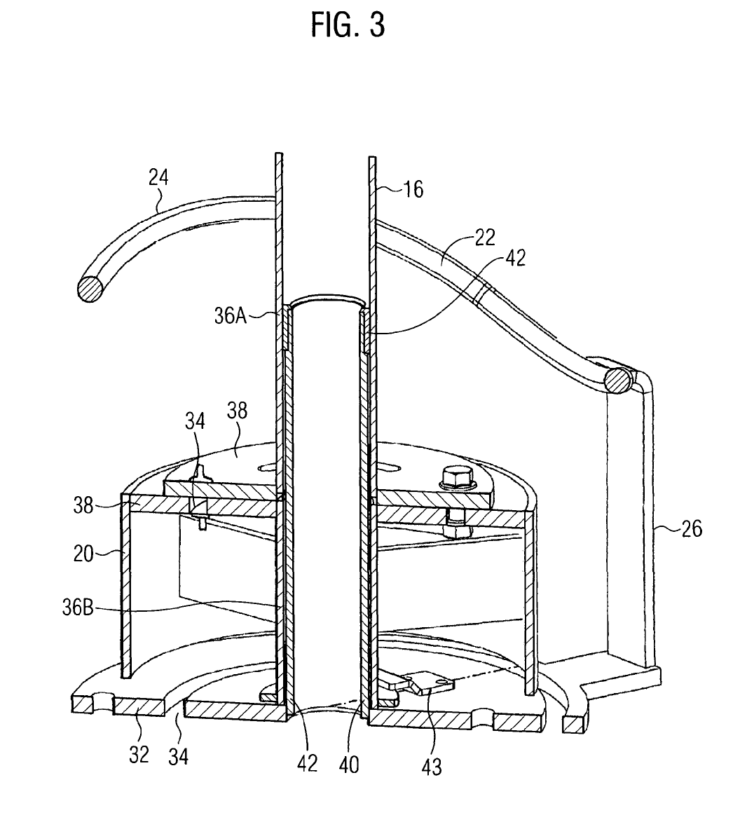

As can be gathered in particular from the illustration according to FIG. 3, the supporting mast 16 is mounted in a rotatable manner on the fastening foot 32. To this end, the fastening foot 32 contains a central supporting tube 40, over which the tubular supporting mast 16 is fitted. In order to avoid running difficulties, in the exemplary embodiment sliding elements of the bearing sleeve 42 type are provided. These are arranged in each case in the lower and upper region of the supporting tube 40. Preferably, the two bearing sleeves 42 have a kind of annular flange. The supporting mast 16 is supported by way of its lower end, at which it likewise forms an annular flange, on this annular flange of the bearing sleeve 42, and so relatively planar contact is formed. The bearing sleeves 42 consist for example of an abrasion-resistant plastic or of a suitable metal.

Furthermore, a storm protection device 43 is provided for the supporting mast 16 such that the supporting mast is secured in particular against lifting axially off the fastening foot 32 while at the same time being rotatable. To this end, in the exemplary embodiment, a form fit which acts in the axial direction is formed between the fastening foot 32 and the supporting mast 16, in particular its bottom flange. The storm protection device 43 is in this case formed in a simple manner by a curved lug, one end of which is fastened to the fastening foot 32 and the other end of which protrudes over the flange, in particular with a small axial spacing.

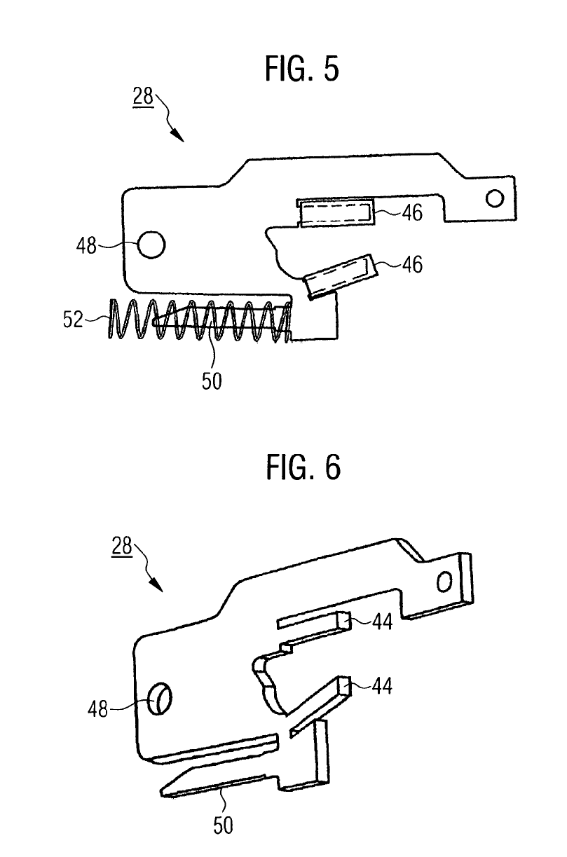

FIGS. 5 and 6 illustrate the configuration of the coupling element 28 as a fork element in more detail. The coupling element 28 contains two fork ends 44. In a preferred configuration, a rotatably mounted sleeve 46 is plugged onto each of the fork ends 44, for example a plastic sleeve or a metal sleeve. In the installed state, these sleeves 46 roll on the guide track 24. In the configuration as a fork element, the curved ring 22 is guided between these sleeves 46. This results in guidance which is as low friction as possible, and so the drive force to be applied by the drive motor 10 can be kept low. In the region of the spring element 52, a shoe collar 53 is arranged on the supporting mast 16.

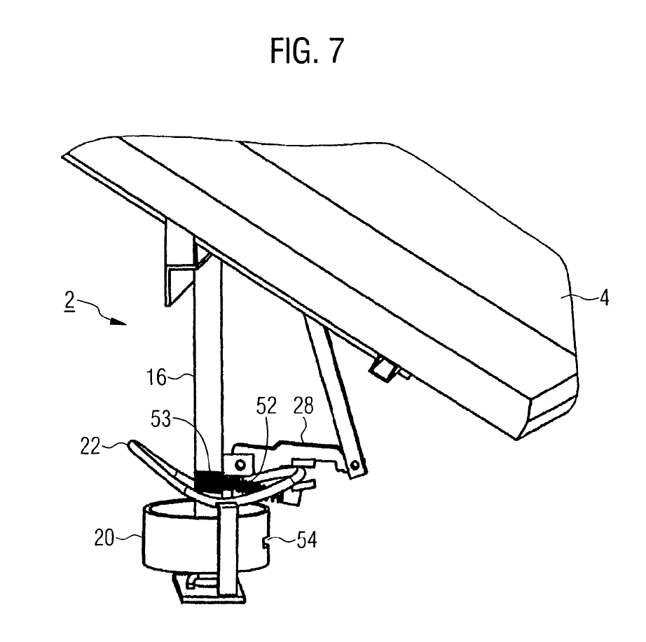

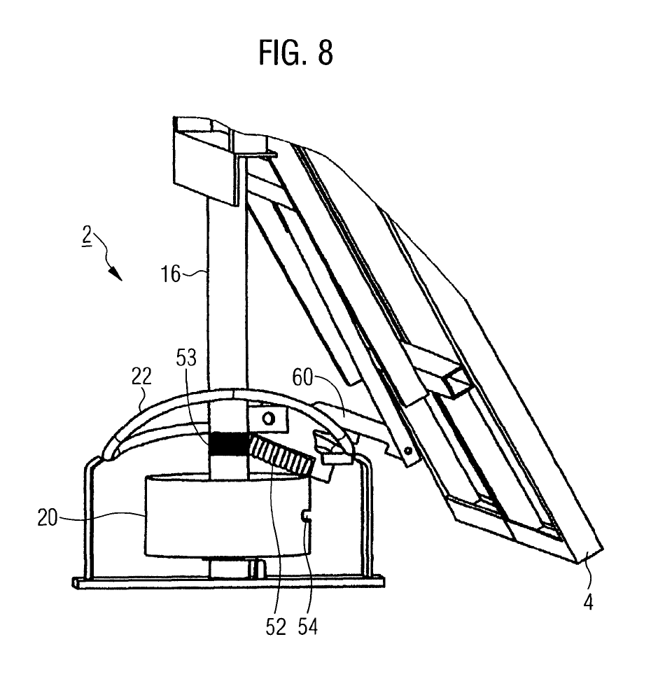

In order to be attached in an articulated manner to the supporting mast 16, the coupling element 28 furthermore has a fastening hole 48. Finally, the coupling element 28 furthermore has a fastening element formed as an extending arm 50, on which a spring element 52, in the exemplary embodiment a compression spring, is pushed. As can be gathered in particular from FIGS. 7 and 8, the spring element 52 acts in the installed state between the coupling element 28 and the supporting mast 16, and is thus supported on the supporting mast 16. The spring element 52 exerts an opposing force directed counter to the inertial force of the photovoltaic module 4. The arrangement of the spring element 52, its size and its spring force/spring constant are therefore selected in a suitable manner to exert this opposing force. As a result, the pressing force transmitted to the elevation element 22 is reduced, and this leads to a smoother-running adjustment movement during a tracking movement and overall relieves the load on the motor 10. Since the force produced by the spring element 52 does not run through the rotary point, defined via the fastening hole 48, of the coupling element 28, the spring element 52 produces a torque which, in the view shown in FIG. 5, is directed in the counterclockwise direction.

Since the spring element 52 subjects the coupling element 28 to the torque, the torque produced by the photovoltaic module 4 is generally counteracted, and so the load on the curved ring 22 is less. Since the forces and moments acting on the curved ring 22 are reduced, the tracking of the photovoltaic module takes place with less outlay in terms of energy. Similarly, the forces acting on the cable 12 are reduced, and so the drive motor 10 can have smaller dimensions or a larger number of supporting frameworks can be connected.

According to FIGS. 2 to 8, a guide slot 54 is furthermore introduced in the driver element 20 and acts as a friction brake for the cable 12. The guide slot 54 extends only over a part region of the lateral surface of the driver element 20. The cable 12 is guided round the lateral surface via the guide slot 54. On account of the tensioning of the cable upon starting up, the cable rests against the rim-side edges (as seen in the circumferential direction) of the guide slot 54, so that the edges form a friction brake that acts in both directions with only little structural outlay.

By way of the described configuration of the supporting framework, cost-effective installation and efficient operation of such a photovoltaic system is possible. By use of the in particular double adjusting device, simple, assembly-friendly and precise alignment of the supporting frameworks 12 in a setpoint rotational position is possible without problems. By way of the further measures, specifically the arrangement of the bearing sleeves 42, the arrangement of the spring element 52 and the arrangement of the sleeves 46, the necessary drive forces and actuating forces for the forced mechanical tracking with respect to the horizontal adjustment movement are kept low overall, and so permanently reliable operation is ensured.

1. A tracking device for a photovoltaic system having at least one photovoltaic module for tracking sun, comprising:
a supporting framework for the photovoltaic module, said supporting framework containing:
a common drive;
a vertical tracking device having a supporting structure supporting the photovoltaic module and mounted in a rotatable manner about a vertical axis, for vertical tracking by means of said common drive, said supporting structure having part regions;
a horizontal tracking device for horizontal tracking of the photovoltaic module by pivoting about a horizontal axis, said horizontal tracking device including an elevation element defining a guide track having different height levels, said supporting structure being rotatable about the vertical axis in relation to said elevation element;
a mechanical coupling device which, in an event of a rotational movement of said supporting structure about said vertical axis, travels with said mechanical coupling element along said guide track and transmits height levels defined by said guide track in order to create a pivoting movement about said horizontal axis;
a drive device;
a driver element disposed concentrically with said supporting framework and connected in a rotationally fixed manner thereto, and provided to transmit an actuating movement of said common drive via said drive device, wherein said driver element is wrapped around in operation by said drive device; and
an adjusting device for a rotational adjustment of said part regions of said supporting structure about said vertical axis with respect to one another.

2. The tracking device according to claim 1, further comprising:
an anchoring element; and
a further adjusting device for a rotational adjustment of said elevation element about said vertical axis with regard to said anchoring element.

3. The tracking device according to claim 1, further comprising:
a fastening foot; and
an anchoring element, said elevation element is connected to said fastening foot which can be fastened reversibly to said anchoring element in different rotational positions.

4. The tracking device according to claim 3, wherein said fastening foot has a fastening plate for resting in a planar manner on said anchoring element.

5. The tracking device according to claim 1, wherein said adjusting device has flanges, said supporting structure divided into said part regions at a dividing point and said part regions can be fixed reversibly together at said dividing point, via said flanges, in different rotational positions with respect to one another.

6. The tracking device according to claim 1, further comprising a spring element disposed between said mechanical coupling element and said supporting structure.

7. The tracking device according to claim 6, wherein said spring element exerts on said mechanical coupling element a torque which counteracts a torque produced by the photovoltaic module with regard to said horizontal axis.

8. The tracking device according to claim 6, wherein said spring element acts on said mechanical coupling element in such a way that a pressing force between said mechanical coupling element and said elevation element is reduced.

9. The tracking device according to claim 6, further comprising a protective collar attached to said supporting structure in a region of said spring element.

10. The tracking device according to claim 1, wherein said mechanical coupling element has at least one rotatably mounted sleeve, by way of which said coupling element travels along said guide track.

11. The tracking device according to claim 1, further comprising:
a fastening foot, said supporting structure having a supporting mast disposed in a rotatable manner on said fastening foot; and
at least one sliding element disposed between said supporting mast and said fastening foot.

12. The tracking device according to claim 11, wherein said supporting mast has a bottom flange, by way of which said supporting mast is supported in a planar manner on said sliding element.

13. The tracking device according to claim 1, wherein said supporting structure is connected in a rotationally fixed manner to said driver element for transmitting the actuating movement exercised by said common drive, and said driver element has a guide slot formed therein in which said drive device, being a cable, which is connected to said common drive, is accommodated in an assembled state.

14. The tracking device according to claim 5, wherein said supporting structure is connected in a rotationally fixed manner to said driver element being a tubular drive element transmitting the actuating movement exercised by said common drive, and one of said flanges forms a cover for said driver element.

15. The tracking device according to claim 1, further comprising:
a fastening foot; and
a storm protection device for securing said supporting structure against lifting axially off said fastening foot, said storm protection device being a lug which is fastened to said fastening foot and projects over a radially extending flange of said supporting structure.

16. The tracking device according to claim 1, wherein said supporting framework is one of a plurality of supporting frameworks, to which said common drive is assigned, and in which the actuating movement exercised by said common drive is transmitted to said plurality of supporting structures via said drive device.

17. The tracking device according to claim 11, wherein said at least one sliding element is a sliding sleeve.

18. The tracking device according to claim 13, wherein said drive device is selected from the group consisting of a flexible drive device and a cable.

19. The tracking device according to claim 1, wherein said supporting framework is one of a plurality of supporting frameworks driven via said drive device.

20. A method for installing a tracking device having a plurality of supporting frameworks fastened to at least one anchoring element, the supporting frameworks having an adjusting device, a common drive, drive device and supporting structures connected to the common drive via the drive device, an actuating movement is transmitted from the common drive to the supporting structures, which comprises the step of:
moving, with an aid of the adjusting device, a first part region of the supporting structures into a setpoint rotational position with respect to a second part region of the supporting structures, at individual ones of the supporting frameworks, as required.
